(19) United States
(12) Patent Application Publication
(10) Pub. No.: US 2024/0128184 A1
(43) Pub. Date: Apr. 18, 2024

(54) ELECTRONIC DEVICE AND MANUFACTURING METHOD THEREOF

(71) Applicant: Innolux Corporation, Miaoli County (TW)

(72) Inventors: Ker-Yih Kao, Miaoli County (TW); Chin-Ming Huang, Miaoli County (TW); Heng-Shen Yeh, Miaoli County (TW)

(73) Assignee: Innolux Corporation, Miaoli County (TW)

(21) Appl. No.: 18/076,374

(22) Filed: Dec. 6, 2022

(30) Foreign Application Priority Data
Oct. 13, 2022 (CN) 202211255346.7

(51) Int. Cl. H01L 23/498; H01L 21/48; H01L 23/00

(52) U.S. Cl. CPC H01L 23/49838; H01L 21/4857; H01L 21/486; H01L 23/49822; H01L 24/16; H01L 24/32; H01L 24/73; H01L 24/92; H01L 2224/16238; H01L 2224/32225; H01L 2224/73204; H01L 2224/92125

(57) ABSTRACT

The disclosure provides an electronic device and a manufacturing method thereof. The electronic device includes a redistribution layer, an electronic unit, and a conductive bump. The redistribution layer includes a first seed layer, a first conductive layer, and a first insulating layer. The first conductive layer is disposed on the first seed layer, the first insulating layer is disposed on the first conductive layer, and an opening of the first insulating layer exposes at least a portion of the first conductive layer. The electronic unit is electrically connected to the redistribution layer. The conductive bump is disposed between the first conductive layer and the electronic unit and is correspondingly disposed in the opening. The electronic unit is electrically connected to the redistribution layer via the conductive bump. The conductive bump is directly in contact with the first conductive layer.

### CROSS-REFERENCE TO RELATED APPLICATION

This application claims the priority benefit of China application serial no. 202211255346.7, filed on Oct. 13, 2022. The entirety of the above-mentioned patent application is hereby incorporated by reference herein and made a part of this specification.

### BACKGROUND

### Technical Field

The disclosure relates to an electronic device and a manufacturing method thereof, and more particularly, to an electronic device with improved reliability and a manufacturing method thereof.

### Description of Related Art

Electronic devices or tiling electronic devices have been widely used in different fields such as communication, display, automotive, high-speed computing, power management, and aviation. With the vigorous development of electronic devices, the electronic devices are developed to be thin and lightweight, and therefore, higher reliability or quality requirements are needed for the electronic devices.

### SUMMARY

The disclosure provides an electronic device and a manufacturing method thereof that may improve the reliability of the electronic device, for example, may reduce loss of signal transmission or may improve transmission quality.

According to an embodiment of the disclosure, an electronic device includes a redistribution layer, an electronic unit, and a conductive bump. The redistribution layer includes a first seed layer, a first conductive layer, and a first insulating layer. The first conductive layer is disposed on the first seed layer, the first insulating layer is disposed on the first conductive layer, and an opening of the first insulating layer exposes at least a portion of the first conductive layer. The electronic unit is electrically connected to the redistribution layer. The conductive bump is disposed between the first conductive layer and the electronic unit and is correspondingly disposed in the opening. The electronic unit is electrically connected to the redistribution layer via the conductive bump. The conductive bump is directly in contact with the first conductive layer.

According to an embodiment of the disclosure, a manufacturing method of an electronic device includes the following steps: forming a redistribution layer, wherein the redistribution layer includes a first conductive layer; forming a conductive bump; and configuring an electronic unit so that the conductive bump is disposed between the electronic unit and the first conductive layer, and the electronic unit is electrically connected to the redistribution layer via the conductive bump. In particular, the conductive bump is directly in contact with the first conductive layer.

### BRIEF DESCRIPTION OF THE DRAWINGS

The accompanying drawings are included to further understand the disclosure, and the drawings are incorporated in the specification and constitute a part of the specification. The drawings illustrate embodiments of the disclosure and, together with the description, serve to explain principles of the disclosure.

FIG. 1A is a schematic top view of an electronic device of an embodiment of the disclosure.

FIG. 1B is a schematic cross-sectional view of the electronic device of FIG. 1A along section line I-I′.

FIG. 2A to FIG. 2E are schematic cross-sectional views of a manufacturing method of an electronic device of an embodiment of the disclosure.

FIG. 3 is a schematic cross-sectional view of a manufacturing method of an electronic device of another embodiment of the disclosure.

FIG. 4 is a schematic cross-sectional view of an electronic device of another embodiment of the disclosure.

FIG. 5 is a schematic cross-sectional view of an electronic device of another embodiment of the disclosure.

### DESCRIPTION OF THE EMBODIMENTS

The disclosure may be understood by referring to the following detailed description in conjunction with the accompanying drawings. It should be noted that in order to facilitate understanding to the reader and to simplify the drawings, the multiple drawings in the disclosure depict a part of the electronic device, and certain elements in the drawings are not drawn to actual scale. In addition, the number and size of each element in the figures are for illustration, and are not intended to limit the scope of the disclosure.

In the following description and claims, the words “including” and “containing” and the like are open words, so they should be interpreted as meaning “including but not limited to . . . ”

It should be understood that when an element or film layer is referred to as “on” or “connected to” to another element or film layer, the element or film layer may be directly on the other element or film layer or directly connected to the other element or layer, or there is an inserted element or film layer between the two (indirect case). Conversely, when an element is referred to as “directly” on or “directly connected” to another element or film layer, there is no intervening element or film layer between the two.

Although the terms “first”, “second”, “third” . . . may be used to describe various constituent elements, the constituent elements are not limited to these terms. These terms are used to distinguish a single constituent element from other constituent elements in the specification. The same terms may be omitted in the claims, and the elements in the claims may be replaced with first, second, third . . . according to the order declared by the elements in the claims. Therefore, in the following description, the first constituent element may be the second constituent element in the claims.

In the text, the terms “about”, “approximately”, “substantially”, “essentially” generally mean within 10%, or within 5%, or within 3%, or within 2%, or within 1%, or within 0.5% of a given value or range. Quantities given herein are approximate quantities, that is, in the absence of a specific description of “about”, “approximately”, “substantially”, “essentially”, the meanings of “about”, “approximately”, “substantially”, “essentially” may still be implied.

In some embodiments of the disclosure, terms such as “connection”, “interconnection”, etc., regarding bonding and connection, unless specifically defined, may mean that two structures are in direct contact, or that two structures are not in direct contact and there are other structures located between these two structures. Moreover, the terms of bonding and connecting may also include the case where both structures are movable or both structures are fixed. In addition, the term “coupled” includes any direct and indirect electrical connection means.

In some embodiments of the disclosure, optical microscopy (OM), scanning electron microscope (SEM), film thickness profiler (α-step), ellipsometer, or other suitable methods may be used to measure the area, width, thickness, or height of each element, or the distance or spacing between the elements. Specifically, according to some embodiments, a scanning electron microscope may be used to obtain a cross-sectional structure image including the elements to be measured, and measure the area, width, thickness, or height of each element, or the distance or spacing between the elements.

The electronic device of the disclosure may include, but is not limited to, a display equipment, a light-emitting device, a solar cell, an antenna device, a sensing device, a vehicle device, or a tiling device. The electronic device may be a bendable or flexible electronic device. The electronic device may, for example, include a liquid-crystal light-emitting diode; the light-emitting diode may include, for example, an organic light-emitting diode (OLED), a sub-millimeter light-emitting diode (mini LED), a micro light-emitting diode (micro LED), or a quantum dot light-emitting diode (quantum dot, QD, for example, QLED or QDLED), fluorescence, phosphor, or other suitable materials, and the materials thereof may be arbitrarily arranged and combined, but the disclosure is not limited thereto. The antenna device may be, for example, a liquid-crystal antenna, but the disclosure is not limited thereto. The tiling device may be, for example, a display tiling device or an antenna tiling device, but the disclosure is not limited thereto. It should be noted that the electronic device may be any combination of the above, but the disclosure is not limited thereto. Hereinafter, an electronic device is used to illustrate the content of the disclosure, but the disclosure is not limited thereto.

It should be noted that in the following embodiments, the features in several different embodiments may be replaced, recombined, and mixed to complete other embodiments without departing from the spirit of the disclosure. As long as the features between the embodiments do not violate the spirit of the disclosure or conflict with each other, they may be mixed and used arbitrarily.

Hereinafter, reference will be made in detail to exemplary embodiments of the disclosure, and examples of the exemplary embodiments are illustrated in the figures. Wherever possible, the same reference numerals are used in the figures and the descriptions to refer to the same or similar portions.

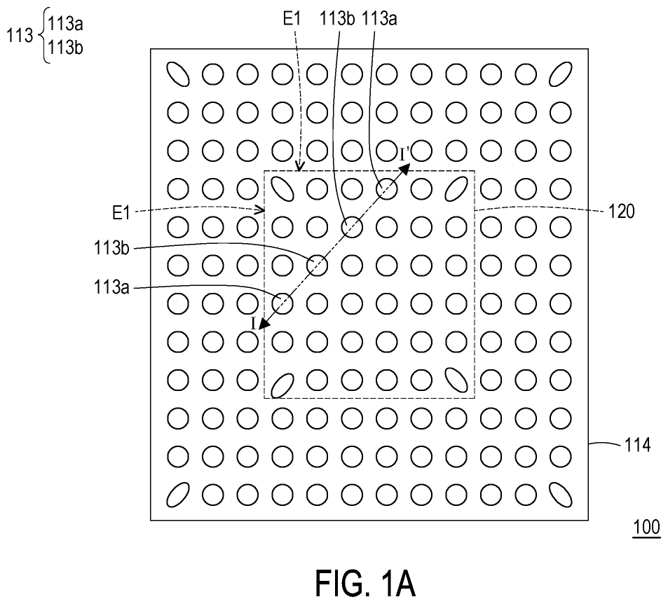

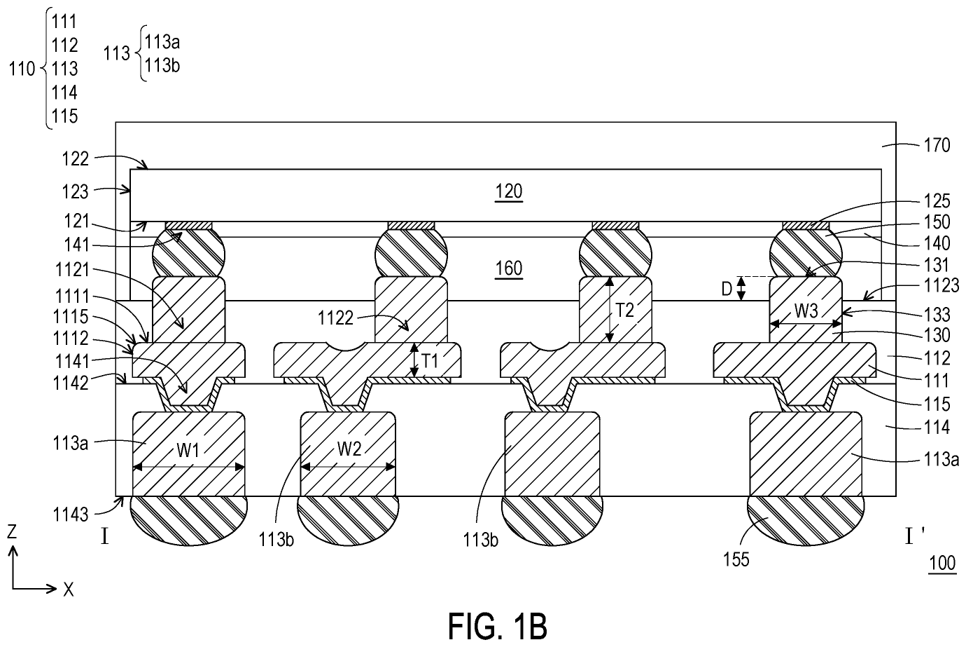

FIG. 1A is a schematic top view of an electronic device of an embodiment of the disclosure. FIG. 1B is a schematic cross-sectional view of the electronic device of FIG. 1A along section line I-I′. For the clarity of the drawings and the convenience of description, FIG. 1A omits to show some elements in an electronic device 100.

Please refer to FIG. 1A and FIG. 1B first, the electronic device 100 of the present embodiment includes a redistribution layer 110, an electronic unit 120, and a conductive bump 130, but the disclosure is not limited thereto. Specifically, in the present embodiment, the redistribution layer 110 includes a first conductive layer 111, an insulating layer 112, another conductive bump 113, an insulating layer 114, and a first seed layer 115, but the disclosure is not limited thereto. In particular, the other conductive bump 113, the insulating layer 114, the first conductive layer 111, and the insulating layer 112 may be stacked in a staggered manner along a normal direction Z of the electronic device 100. The first conductive layer 111 is the conductive layer closest to the electronic unit 120 in the redistribution layer 110, but the disclosure is not limited thereto.

The other conductive bump 113 may include a conductive bump 113a and a conductive bump 113b. In the top view of the electronic device 100 (shown in FIG. 1A), the conductive bump 113a is adjacent to an edge E1 of the electronic unit 120, and the conductive bump 113b is further away from the edge E1 of the electronic unit 120 than the conductive bump 113a. The other conductive bump 113 may be a single-layer structure or a multi-layer structure. The material of the other conductive bump 113 may include copper, titanium, chromium, aluminum, gold, nickel, tin, silver, an alloy of the above metals, other suitable conductive materials, or a combination of the above, but the disclosure is not limited thereto. In the present embodiment, the object of the other conductive bump 113 is similar to that of under-bump metallization (UBM) for connecting to a first external element (e.g., a printed circuit board (PCB)) and transmitting signals, but the disclosure is not limited thereto. According to some embodiments, the first external element may be, for example, a driving circuit, a resistor, a capacitor, an inductor, an antenna, or other suitable elements, but the disclosure is not limited thereto.

Please continue to refer to FIG. 1B, the conductive bump 113a has a width W1, and the conductive bump 113b has a width W2. In particular, the width W1 is, for example, the width of the conductive bump 113a measured along a direction X, and the width W2 is, for example, the width of the conductive bump 113b measured along the direction X. The direction X and the normal direction Z are respectively different directions. The direction X is substantially perpendicular to the normal direction Z, and the direction X may be regarded as the horizontal direction of FIG. 1B. In the present embodiment, the width W1 may be greater than the width W2, but the disclosure is not limited thereto. According to some embodiments, the width W1 may be equal to the width W2, but the disclosure is not limited thereto. By designing bumps with different widths at different positions corresponding to the edge E1 of the electronic unit 120, for example, the effect of relieving the stress of the electronic device and improving reliability may be achieved.

The insulating layer 114 is disposed on the other conductive bump 113. The insulating layer 114 has an opening 1141, and the opening 1141 exposes a portion of the other conductive bump 113. The insulating layer 114 has an upper surface 1142 and a lower surface 1143 opposite to each other. The insulating layer 114 may be a single-layer structure or a multi-layer structure, and the material of the insulating layer 114 may include photosensitive polyimide (PSPI), Ajinomoto build-up layer (ABF), other suitable insulating materials, or a combination of the above, but the disclosure is not limited thereto.

The first seed layer 115 is disposed on the upper surface 1142 of the insulating layer 114 and in the opening 1141. The first seed layer 115 may expose a portion of the insulating layer 114. The first seed layer 115 may be a single-layer or multi-layer metal layer, and the material of the first seed layer 115 may include titanium, copper, aluminum, nickel, indium-tin oxide (ITO), other suitable conductive materials, or a combination of the above, but the disclosure is not limited thereto. In some embodiments, the first seed layer 115 may be regarded as a seed layer, and conductive bumps may be formed on the seed layer via a suitable process, such as electroplating, photo process, etch process, grinding process, laser process, but the disclosure is not limited thereto.

The first conductive layer 111 is disposed on the first seed layer 115 and in the opening 1141, so that the first seed layer 115 may be located between the first conductive layer 111 and the other conductive bump 113, and the first conductive layer 111 may be electrically connected to the other conductive bump 113 via the first seed layer 115. The first conductive layer 111 may be a single-layer structure or a multi-layer structure. The material of the first conductive layer 111 may include copper, titanium, chromium, aluminum, gold, nickel, tin, silver, alloys of the above metals, other suitable conductive materials, or a combination of the above, but the disclosure is not limited thereto.

The first conductive layer 111 has an upper surface 1111 and a side surface 1112. The upper surface 1111 is the surface of the first conductive layer 111 facing away from the first seed layer 115. The side surface 1112 is connected to the upper surface 1111. In the present embodiment, the first conductive layer 111 may have a curved edge 1115. In particular, the curved edge 1115 is located at the connection of the upper surface 1111 and the side surface 1112 of the first conductive layer 111. In addition, the design of the curved edge 1115 may reduce the issue of cracking of the insulating layer 112, thereby improving the reliability or transmission quality of the electronic device. According to some embodiments, the first conductive layer 111 has the upper surface 1111, wherein the upper surface 1111 may have a concave or arc shape, but the disclosure is not limited thereto. According to some embodiments, a lower surface of the other conductive bump 113 may have a concave or arc shape, but the disclosure is not limited thereto. According to some embodiments, the surface of the conductive surface and the surface of the insulating layer may be co-planar. According to some embodiments, the surface of the conductive layer and the surface of the conductive bump may be protruded outward or higher than the surface of the insulating layer. According to some embodiments, the surface of the conductive layer and the surface of the conductive bump may be lower than the surface of the insulating layer.

The first conductive layer 111 has a thickness T1, and the thickness T1 is, for example, the thickness of the first conductive layer 111 measured along the normal direction Z of the electronic device 100.

The insulating layer 112 is disposed on the first conductive layer 111. The insulating layer 112 may cover a portion of the insulating layer 114 and a portion of the first conductive layer 111. The insulating layer 112 has openings 1121 and 1122, and the openings 1121 and 1122 expose a portion of the first conductive layer 111. The opening 1121 may be overlapped with the opening 1141 of the insulating layer 114 in the normal direction Z of the electronic device 100, and the opening 1122 may be not overlapped with the opening 1141 of the insulating layer 114 in the normal direction Z of the electronic device 100. The insulating layer 112 further has an upper surface 1123, and the upper surface 1123 may be the surface of the insulating layer 112 facing away from the insulating layer 114. The insulating layer 112 may be a single-layer structure or a multi-layer structure, and the material of the insulating layer 112 may include photosensitive polyimide (PSPI), Ajinomoto build-up layer (ABF), other suitable insulating materials, or a combination of the above, but the disclosure is not limited thereto. Via the design that the opening 1121 may be overlapped with the opening 1141 of the insulating layer 114 in the normal direction Z of the electronic device 100, signal transmission efficiency may be improved or noise may be reduced. Via the design that the opening 1121 may be not overlapped with the opening 1141 of the insulating layer 114 in the normal direction Z of the electronic device 100, heat dissipation path may be increased.

The conductive bump 130 is disposed on the insulating layer 112, in the opening 1121, and in the opening 1122, so that the first conductive layer 111 may be disposed between the conductive bump 130 and the other conductive bump 113, and the conductive bump 130 may be disposed between the electronic unit 120 and the first conductive layer 111. The conductive bump 130 may be not overlapped with the side surface 123 of the electronic unit 120 in the normal direction Z of the electronic device 100 may reduce the risk of breakage of the conductive bump, but the disclosure is not limited thereto. The conductive bump 130 may be directly in contact with the first conductive layer 111. In the present embodiment, the conductive bump 130 and the first conductive layer 111 may be made of the same material, and thus is not be repeated herein. In the present embodiment, the conductive bump 130 and the first conductive layer 111 may be formed via the same electroplating current transmission path, but the disclosure is not limited thereto. In the present embodiment, the outline shape of the conductive bump 130 may be, for example, a rectangle, but the disclosure is not limited thereto. In some embodiments, the outline shape of the conductive bump may also be a trapezoid.

The conductive bump 130 has a thickness T2, and the thickness T2 is, for example, the thickness of the conductive bump 130 measured along the normal direction Z of the electronic device 100. In the present embodiment, the thickness T2 of the conductive bump 130 may be greater than or equal to the thickness T1 of the first conductive layer 111 (i.e., T1≤T2), but the disclosure is not limited thereto. The conductive bump 130 has a width W3, and the width W3 is, for example, the width of the conductive bump 130 measured along the direction X. In the present embodiment, the ratio of the width W3 to the width W1 may be less than or equal to the ratio of the width W3 to the width W2 (i.e., W3/W1≤W3/W2), but the disclosure is not limited thereto.

The conductive bump 130 has an upper surface 131 and a side surface 133. The upper surface 131 may be the surface of the conductive bump 130 facing away from the first conductive layer 111, and the side surface 133 is connected to the upper surface 131. In the present embodiment, the upper surface 131 of the conductive bump 130 may be higher than the upper surface 1123 of the insulating layer 112 of the redistribution layer 110 in the normal direction Z of the electronic device 100, and a portion of the side surface 133 may be exposed by the insulating layer 112, but the disclosure is not limited thereto. There is a distance D between the upper surface 131 of the conductive bump 130 and the upper surface 1123 of the insulating layer 112, and the distance D is, for example, the distance measured along the normal direction Z of the electronic device 100 between the upper surface 131 of the conductive bump 130 and the upper surface 1123 of the insulating layer 112. In the present embodiment, the ratio of the distance D to the thickness T2 may be greater than 0 and less than or equal to 0.3 (i.e., 0<D/T2≤0.3). The above design helps the alignment accuracy of subsequent elements, but the disclosure is not limited thereto. The upper surface 131 of the conductive bump 130 according to the disclosure may be regarded as, for example, the upper surface 131 of the conductive bump 130 when the electronic device is finished.

In the present embodiment, the object of the conductive bump 130 is similar to that of bump metal for connecting to a second external element (e.g., the electronic unit 120) and transmitting signals, but the disclosure is not limited thereto.

The electronic unit 120 is disposed on the redistribution layer 110 and the conductive bump 130, and the electronic unit 120 may be electrically connected to the redistribution layer 110. In the present embodiment, the electronic unit 120 may be electrically connected to the redistribution layer 110 via, for example, the conductive bump 130. The electronic unit 120 has a first surface 121, a second surface 122, and a side surface 123. The first surface 121 faces the redistribution layer 110, the first surface 121 and the second surface 122 are opposite to each other, and the side surface 123 is connected to the first surface 121 and the second surface 122. The electronic unit 120 includes a pad 125, and the pad 125 is disposed on the first surface 121. The material of the pad 125 may include aluminum, titanium, copper, molybdenum, tin, silver, other suitable conductive materials, or a combination of the above, but is not limited to. In the present embodiment, the electronic unit 120 may include a chip (for example, a known good die (KGD)), a diode, an antenna unit, a sensor, a structure related to semiconductor processes, or a structure related to a semiconductor process disposed on a substrate (e.g., polyimide, glass, silicon substrate, or other suitable substrate materials), but the disclosure is not limited thereto.

In the present embodiment, the electronic device 100 further includes an insulating layer 140, a conductive member 150, an underfill 160, a protective layer 170, and a conductive member 155.

The insulating layer 140 is disposed on the first surface 121 of the electronic unit 120. The insulating layer 140 has an opening 141, and the opening 141 exposes the pad 125. The insulating layer 140 may have a single-layer structure or a multi-layer structure, and the material of the insulating layer 140 may include silicon oxide, silicon nitride, other suitable inorganic materials, or a combination of the above, but the disclosure is not limited thereto.

The conductive member 150 is disposed on the conductive bump 130 and in the opening 141, so that the conductive member 150 may be located between the electronic unit 120 and the conductive bump 130. The conductive member 150 may be electrically connected to the pad 125 and the conductive bump 130. In the present embodiment, the conductive member 150 may be a solder ball, and the material of the conductive member 150 may include tin-silver (SnAg), tin, silver, nickel, gold, copper, conductive paste, or a suitable conductive metal thereof, but the disclosure is not limited thereto. In some embodiments, when the thickness T2 of the conductive bump 130 is greater than or equal to the thickness T1, connection quality between the conductive bump and the conductive member 150 may be improved. For example, the redistribution layer 110 is electrically connected to the electronic unit 120 via the conductive bump 130 and the conductive member 150, wherein since the conductive bump 130 and the conductive member 150 may undergo solid solution reaction to improve the bonding ability between elements, the thickness T2 of the conductive bump 130 may be greater than or equal to the thickness T1 of the first conductive layer 111.

The underfill 160 is disposed between the electronic unit 120 and the conductive bump 130, and disposed between the insulating layer 140 and the insulating layer 112. In particular, the underfill 160 may cover the conductive bump 130.

The protective layer 170 is disposed on the second surface 122 of the electronic unit 120. The protective layer 170 may cover the second surface 122 and the side surface 123 of the electronic unit 120 to surround the electronic unit 120. The protective layer 170 may cover the side surface of the insulating layer 140 and the side surface of the underfill 160. The material of the protective layer 170 may include epoxy molding compound (EMC), other suitable protective materials, or a combination of the above, but the disclosure is not limited thereto.

The conductive member 155 is disposed on the lower surface 1143 of the insulating layer 114. The conductive member 155 may be electrically connected to the other conductive bump 113. In the present embodiment, the conductive member 155 may be a solder ball, and the material of the conductive member 155 may be the same as the material of the conductive member 150, so the details are not repeated herein.

In the present embodiment, the first external element (e.g., printed circuit board) may pass through the other conductive bump 113, the first seed layer 115, the first conductive layer 111, and the conductive bump 130 via signal transmission with the second external element (e.g., the electronic unit 120).

In the present embodiment, since the conductive bump 130 may be directly in contact with the first conductive layer 111 and the conductive bump 130 and the first conductive layer 111 may have the same material, compared with the general need to provide other conductive layers (such as seed layers) of different materials between the first conductive layer and the conductive bump, the electronic device 100 in the present embodiment may have the effect of reducing loss of signal transmission or improving transmission quality. The other conductive layers of different materials may be, for example, seed layers, but the disclosure is not limited thereto. In particular, the other conductive layers of different materials may be regarded as the resistance between the first conductive layer and the conductive bumps. Therefore, the disposition of the other conductive layers of different materials increases loss of signal transmission between the first conductive layer and the conductive bumps, thereby reducing transmission quality.

Although the redistribution layer 110 of the present embodiment includes three metal layers (i.e., the first conductive layer 111, the other conductive bump 113, and the first seed layer 115) and two insulating layers (i.e., the insulating layer 112 and the insulating layer 114), the disclosure does not limit the number of metal layers and insulating layers in the redistribution layer. In some embodiments, the redistribution layer may also include one or more other metal layers and other insulating layers.

In the present embodiment, due to the design of the redistribution layer 110, the electronic device 100 of the present embodiment may reduce loss of signal transmission or improve transmission quality, so that the electronic device 100 of the present embodiment may be applied to a power module or a product with high frequency requirements.

Other embodiments are listed below for description. It must be noted here that the following embodiments adopt the reference numerals and part of the content of the above embodiments, wherein the same reference numerals are used to represent the same or similar elements, and the description of the same technical content is omitted. For the description of the omitted parts, reference may be made to the above embodiments, which is not repeated in the following embodiments.

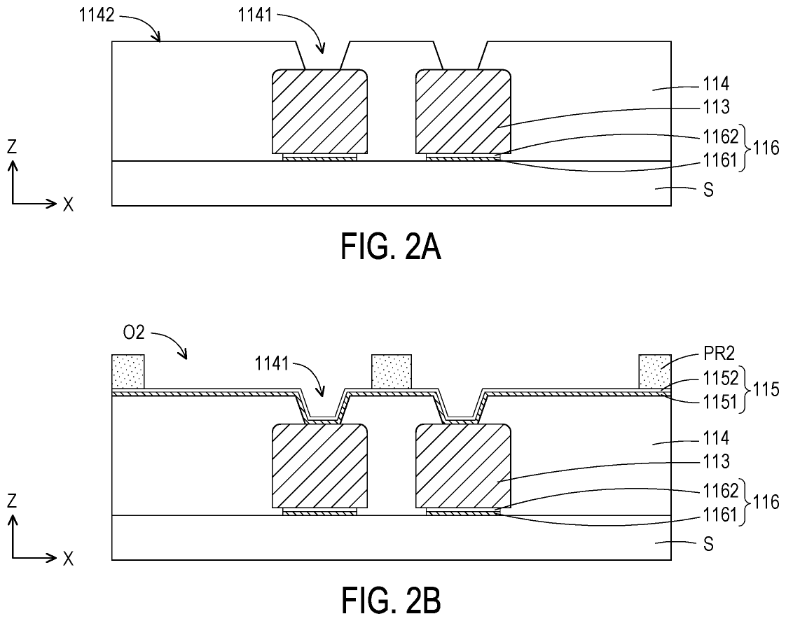

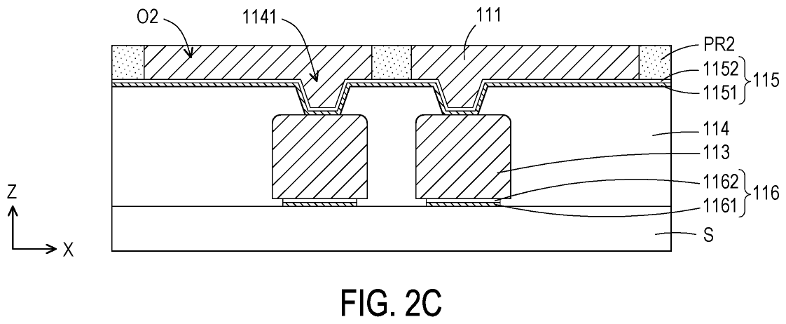

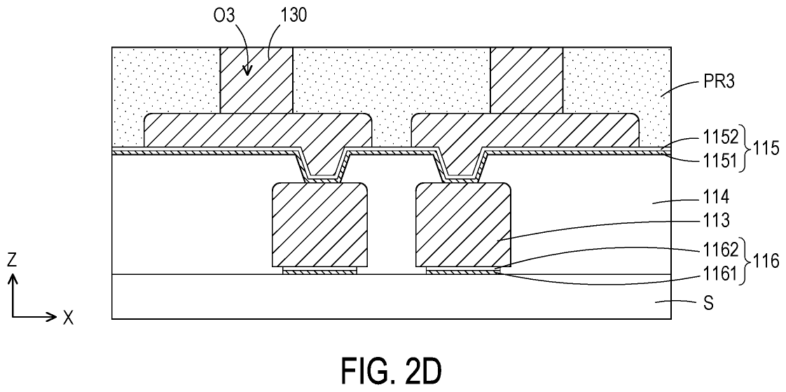

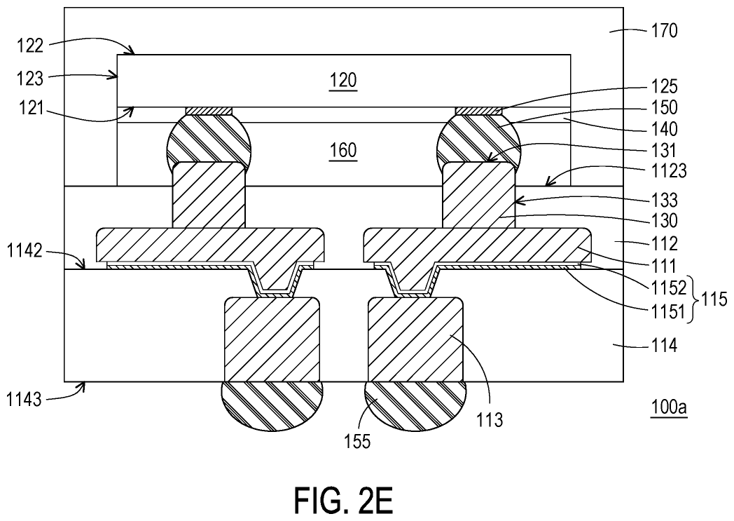

FIG. 2A to FIG. 2E are schematic cross-sectional views of a manufacturing method of an electronic device of an embodiment of the disclosure. The same or similar members in the embodiment of FIG. 2A to FIG. 2E and the embodiment of FIG. 1 are made of the same materials or methods, so the same and similar descriptions in the two embodiments are not repeated herein.

In the present embodiment, the manufacturing method of an electronic device 100a may include the following steps.

Referring to FIG. 2A to FIG. 2E, the redistribution layer 110 is formed, the conductive bump 130 is formed, and the electronic unit 120 is configured. Specifically, the method of forming the redistribution layer 110 may include the following steps.

Referring to FIG. 2A first, a substrate S is provided. The substrate S may include a rigid substrate, a flexible substrate, or a combination of the above. For example, the material of the substrate S may include glass, quartz, sapphire, ceramics, polycarbonate (PC), polyimide (PI), polyethylene terephthalate (PET), other suitable substrate materials, or a combination of the above, but the disclosure is not limited thereto.

Next, a seed layer 116 is formed on the substrate S, wherein the seed layer 116 may include a first layer 1161 and a second layer 1162 located on the first layer 1161. Next, a first photoresist (not shown) is formed on the seed layer 116, wherein the first photoresist has a first opening (not shown) to expose a portion of the seed layer 116. Next, the other conductive bump 113 is formed on the seed layer 116 in the first opening. Next, the first photoresist is removed to expose another portion of the seed layer 116. Next, the other portion of the seed layer 116 that is exposed is removed. Next, an insulating layer 114 is formed on the other conductive bump 113, wherein the insulating layer 114 has the opening 1141, and the opening 1141 exposes a portion of the other conductive bump 113.

Then, referring to FIG. 2B, the first seed layer 115 is formed on the upper surface 1142 of the insulating layer 114 and in the opening 1141, wherein the first seed layer 115 may include a first layer 1151 and a second layer 1152 located on the first layer 1151. Next, a second photoresist PR2 is formed on the first seed layer 115, wherein the second photoresist PR2 has a second opening O2, and the second opening O2 exposes a portion of the first seed layer 115.

Then, referring to FIG. 2C, the first conductive layer 111 is formed on the first seed layer 115 in the second opening O2 and in the opening 1141 of the insulating layer 114.

Then, referring to FIG. 2D, the second photoresist PR2 is removed to expose another portion of the first seed layer 115. Next, a third photoresist PR3 is formed on the first conductive layer 111, wherein the third photoresist PR3 has a third opening O3, and the third opening O3 exposes a portion of the first conductive layer 111. The third opening O3 may be overlapped with the opening 1141 of the insulating layer 114 in the normal direction Z of the substrate S. Next, using the first seed layer 115 as an electroplating current transmission path, the conductive bump 130 is directly formed on the first conductive layer 111 in the third opening O3, so that the conductive bump 130 may be directly in contact with the first conductive layer 111.

Then, referring to FIG. 2E, the third photoresist PR3 is removed to expose the other portion of the first seed layer 115. Next, the other portion of the first seed layer 115 that is exposed is removed. Next, the insulating layer 112 is formed on the conductive bump 130 and the first conductive layer 111. Next, the upper surface 131 and a portion of the side surface 133 of the conductive bump 130 may be exposed from the insulating layer 112 by grinding, yellow light, or a suitable patterning process. Here, the redistribution layer 110 is substantially completed, wherein the redistribution layer 110 includes the first conductive layer 111, the insulating layer 112, the other conductive bump 113, the insulating layer 114, and the first seed layer 115. According to some embodiments, a portion of the insulating layer 112 is disposed between the first conductive layer 111 and the insulating layer 114. Via the above design, for example, the adhesive force between different film layers may be improved, but the disclosure is not limited thereto.

Next, referring further to FIG. 2E, the electronic unit 120 is bonded onto the conductive bump 130 via the conductive member 150, so that the conductive bump 130 may be disposed between the electronic unit 120 and the first conductive layer 111, and the electronic unit 120 may be electrically connected to the redistribution layer 110 via the conductive bump 130. Next, the underfill 160 is formed between the electronic unit 120 and the conductive bump 130. Next, the protective layer 170 is formed on the second surface 122 of the electronic unit 120 to surround the electronic unit 120. Next, the substrate S is removed. Next, the seed layer 116 is removed. Next, the conductive member 155 is formed on the lower surface 1143 of the insulating layer 114, so that the conductive member 155 is electrically connected to the other conductive bump 113. Here, the electronic device 100a is substantially completed. According to some embodiments, the conductive member 150 may cover at least a portion of a side of the conductive bump 130 to increase the connection, but the disclosure is not limited thereto.

In the present embodiment, since the conductive bump 130 may be overlapped with the other conductive bump 113 in the normal direction Z of the electronic device 100a, the path for the electronic unit 120 to be electrically connected to the conductive member 155 may be shortened, thereby reducing impedance.

In the present embodiment, the conductive bump 130 may be directly formed on the first conductive layer 111 by using the first seed layer 115 as an electroplating current transmission path. Compared with the general method in which other conductive layers (such as seed layers) of different materials are needed between the first conductive layer and the conductive bump to perform electroplating, the electronic device 100a and the manufacturing method thereof of the present embodiment may omit the process of forming other conductive layers of different materials or lower costs, and the electronic device 100a and the manufacturing method thereof of the present embodiment may also have the effect of reducing loss of signal transmission or improving transmission quality by directly bringing the conductive bump 130 in contact with the first conductive layer 111.

Although the manufacturing method of the electronic device 100a of the present embodiment omits other conductive layers (e.g., seed layers) of different materials generally needed to be disposed between the first conductive layer and the conductive bumps as an example, the disclosure is not limited thereto. In some embodiments, the first seed layer between the first conductive layer and the other conductive bump may also be omitted. In some embodiments, when the redistribution layer further includes other conductive layers, the other conductive layers may also be formed by omitting the seed layer, so as to reduce loss of signal transmission.

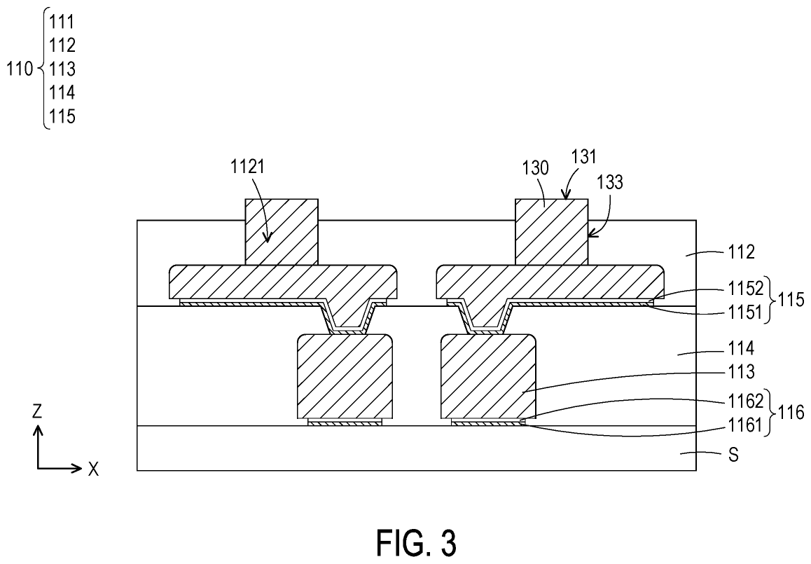

FIG. 3 is a schematic cross-sectional view of a manufacturing method of an electronic device of another embodiment of the disclosure. FIG. 3 is a continuation of the steps of FIG. 2C instead of FIG. 2D, and FIG. 3 is a step that may be continued to form the electronic device 100a shown in FIG. 2E. The same or similar members in the embodiment of FIG. 3 and the embodiment of FIG. 2A to FIG. 2D are made of the same materials or methods, so the same and similar descriptions in the two embodiments are not repeated herein, and mainly the differences between the two embodiments are described.

Specifically, referring to FIG. 3, the second photoresist PR2 is removed to expose another portion of the first seed layer 115. Next, the other portion of the first seed layer 115 that is exposed is removed. Next, the insulating layer 112 is formed on the first conductive layer 111, wherein the insulating layer 112 has the opening 1121, and the opening 1121 exposes a portion of the first conductive layer 111. The opening 1121 may be overlapped with the opening 1141 of the insulating layer 114 in the normal direction Z of the substrate S. Next, using the first conductive layer 111 as an electroplating current transmission path, the conductive bump 130 is directly formed on the first conductive layer 111 in the opening 1121, so that the conductive bump 130 may be directly in contact with the first conductive layer 111. Next, the insulating layer 112 is ground to expose the upper surface 131 and a portion of the side surface 133 of the conductive bump 130. Here, the redistribution layer 110 is substantially completed, wherein the redistribution layer 110 includes the first conductive layer 111, the insulating layer 112, the other conductive bump 113, the insulating layer 114, and the first seed layer 115.

Next, referring to FIG. 2E, the electronic unit 120 is bonded onto the conductive bump 130 via the conductive member 150, so that the conductive bump 130 may be disposed between the electronic unit 120 and the first conductive layer 111, and the electronic unit 120 may be electrically connected to the redistribution layer 110 via the conductive bump 130. Next, the underfill 160 is formed between the electronic unit 120 and the conductive bump 130. Next, the protective layer 170 is formed on the second surface 122 of the electronic unit 120 to surround the electronic unit 120. Next, the substrate S is removed. Next, the seed layer 116 is removed. Next, the conductive member 155 is formed on the lower surface 1143 of the insulating layer 114, so that the conductive member 155 is electrically connected to the other conductive bump 113. Here, the electronic device 100a is substantially completed.

In the present embodiment, the conductive bump 130 may be directly formed on the first conductive layer 111 by using the first conductive layer 111 as an electroplating current transmission path. Compared with the general method in which other conductive layers of different materials are needed between the first conductive layer and the conductive bump to perform electroplating, an electronic device 100b and the manufacturing method thereof of the present embodiment may omit the process of forming other conductive layers of different materials or lower costs, and the electronic device 100b and the manufacturing method thereof of the present embodiment may also have the effect of reducing loss of signal transmission or improving transmission quality by directly bringing the conductive bump 130 in contact with the first conductive layer 111.

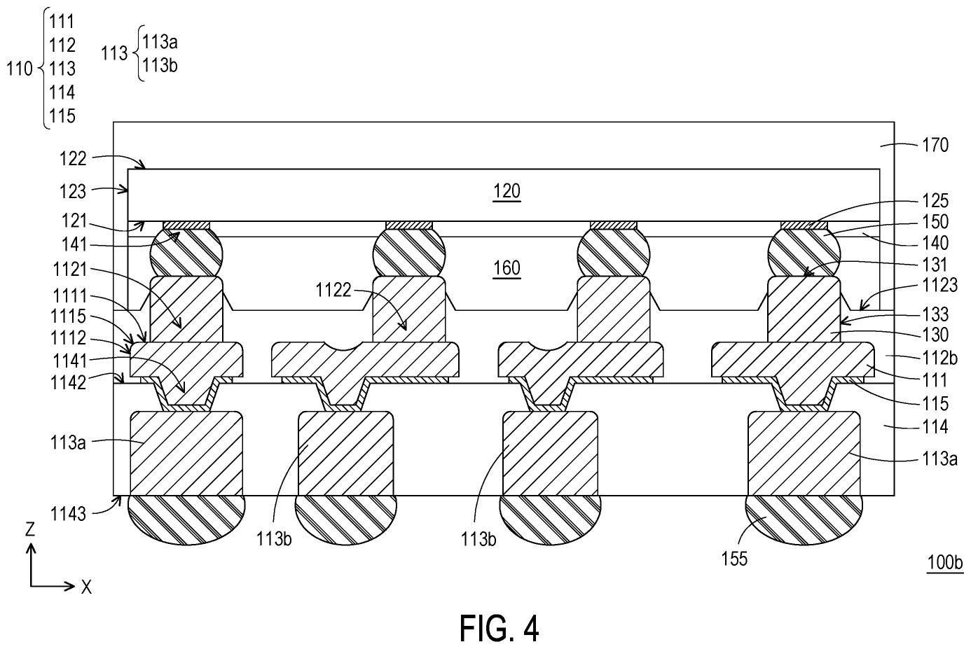

FIG. 4 is a schematic cross-sectional view of an electronic device of another embodiment of the disclosure. Please refer to FIG. 1B and FIG. 4 at the same time, the electronic device 100b of the present embodiment is similar to the electronic device 100 in FIG. 1B, but the differences between the two are: in the electronic device 100b of the present embodiment, an insulating layer 112b may also partially be in contact with the side surface 133 of the conductive bump 130 higher than the insulating layer 112b near the conductive bump 130. In detail, the insulating layer 112b is in contact with the side surface 133 from a direction parallel to the normal direction Z of the electronic device 100b and toward the upper surface 131 of the conductive bump 130.

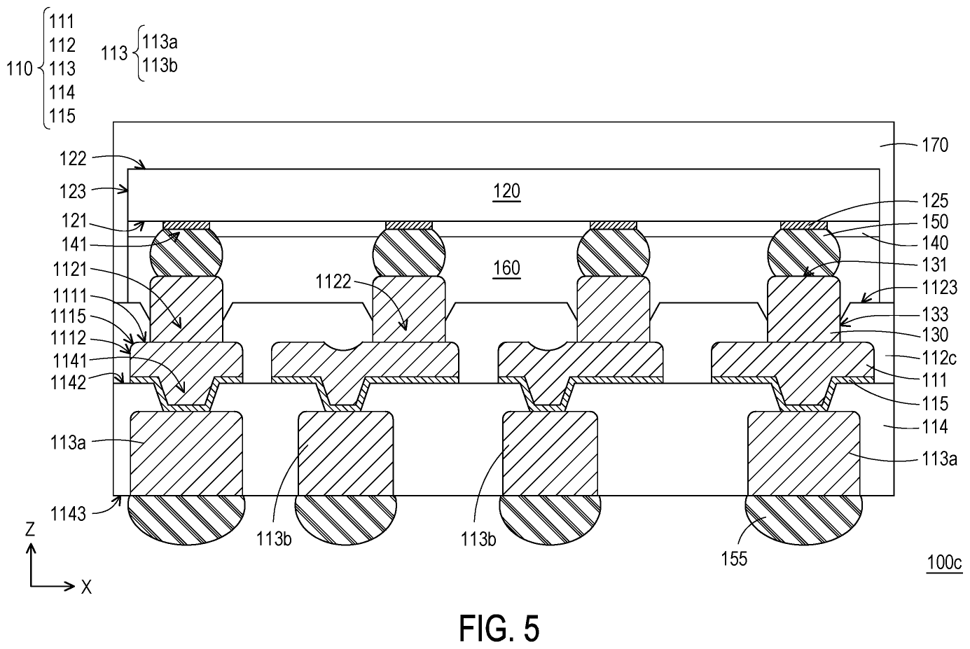

FIG. 5 is a schematic cross-sectional view of an electronic device of another embodiment of the disclosure. Please refer to FIG. 1B and FIG. 5 at the same time, an electronic device 100c of the present embodiment is similar to the electronic device 100 in FIG. 1B, but the differences between the two are: in the electronic device 100c of the present embodiment, the insulating layer 112c may further have a recess near the conductive bump 130. In detail, the insulating layer 112c is recessed downward from a direction parallel to the normal direction Z of the electronic device 100b and toward the first conductive layer 111.

Based on the above, in the electronic device and the manufacturing method thereof of the embodiments of the disclosure, since the conductive bump may be directly in contact with the first conductive layer and the conductive bump may have the same material as the first conductive layer, compared with the general need to provide other conductive layers of different materials between the first conductive layer and the conductive bump, the electronic device in the present embodiment may have the effect of reducing loss of signal transmission or improving transmission quality. Since in the present embodiment, the first conductive layer or the first seed layer may be used as an electroplating current transmission path to directly form the conductive bump on the first conductive layer, compared with the general method in which other conductive layers of different materials need to be disposed between the first conductive layer and the conductive bump for electroplating, the electronic device and the manufacturing method thereof of the present embodiment may omit the manufacturing process that generally requires other conductive layers of different materials, or may lower costs.

Lastly, it should be noted that the above embodiments are used to describe the technical solution of the disclosure instead of limiting it. Although the disclosure has been described in detail with reference to each embodiment above, those having ordinary skill in the art should understand that the technical solution recited in each embodiment above may still be modified, or some or all of the technical features thereof may be equivalently replaced. These modifications or replacements do not make the essence of the corresponding technical solutions depart from the scope of the technical solution of each embodiment of the disclosure.

What is claimed is:

1. An electronic device, comprising:
a redistribution layer comprising a first seed layer, a first conductive layer, and a first insulating layer, wherein the first conductive layer is disposed on the first seed layer, the first insulating layer is disposed on the first conductive layer, and a first opening of the first insulating layer exposes at least a portion of the first conductive layer;
an electronic unit electrically connected to the redistribution layer; and
a conductive bump disposed between the electronic unit and the first conductive layer and correspondingly disposed in the first opening, wherein the electronic unit is electrically connected to the redistribution layer via the conductive bump,
wherein the conductive bump is directly in contact with the first conductive layer.

2. The electronic device of claim 1, wherein the first conductive layer has a curved edge.

3. The electronic device of claim 1, wherein the first conductive layer has a first thickness, the conductive bump has a second thickness, and the second thickness is greater than or equal to the first thickness.

4. The electronic device of claim 1, wherein an upper surface of the conductive bump is higher than the first insulating layer of the redistribution layer.

5. The electronic device of claim 4, wherein the conductive bump has a thickness, there is a distance between the upper surface of the conductive bump and an upper surface of the first insulating layer, and a ratio of the distance to the thickness is greater than 0 and less than or equal to 0.3.

6. The electronic device of claim 1, wherein the redistribution layer further comprises:
another conductive bump, wherein the first seed layer is disposed between the first conductive layer and the other conductive bump.

7. The electronic device of claim 6, wherein the first conductive layer is electrically connected to the other conductive bump via the first seed layer.

8. The electronic device of claim 6, wherein the other conductive bump comprises a first conductive bump and a second conductive bump, the first conductive bump is closer to an edge of the electronic unit than the second conductive bump, and a width of the first conductive bump is greater than a width of the second conductive bump.

9. The electronic device of claim 6, wherein the redistribution layer further comprises:
a second insulating layer disposed on the other conductive bump and having a second opening,
wherein the second opening exposes a portion of the other conductive bump, and the first seed layer is disposed on an upper surface of the second insulating layer and in the second opening.

10. The electronic device of claim 9, wherein the second opening of the second insulating layer is overlapped with the first opening of the first insulating layer in a normal direction of the electronic device.

11. The electronic device of claim 1, wherein the conductive bump has a same material as the first conductive layer.

12. The electronic device of claim 1, wherein the first conductive layer is a conductive layer closest to the electronic unit in the redistribution layer.

13. The electronic device of claim 1, wherein the conductive bump is not overlapped with a side surface of the electronic unit in a normal direction of the electronic device.

14. The electronic device of claim 1, further comprising:
a conductive member disposed on the conductive bump and electrically connected to a pad of the electronic unit and the conductive bump.

15. The electronic device of claim 1, wherein the first insulating layer is partially in contact with a side surface of the conductive bump higher than the first insulating layer near the conductive bump, or the first insulating layer has a recess near the conductive bump.

16. A manufacturing method of an electronic device, comprising:
forming a redistribution layer, wherein the redistribution layer comprises a first conductive layer;
forming a conductive bump; and
configuring an electronic unit so that the conductive bump is disposed between the electronic unit and the first conductive layer, and the electronic unit is electrically connected to the redistribution layer via the conductive bump,
wherein the conductive bump is directly in contact with the first conductive layer.

17. The manufacturing method of the electronic device of claim 16, wherein a method of forming the redistribution layer comprises:
providing a substrate;
forming a seed layer on the substrate;
forming another conductive bump on the seed layer;
forming a first insulating layer on the other conductive bump, wherein the first insulating layer has an opening, and the opening exposes a portion of the other conductive bump;
forming a first seed layer on an upper surface of the first insulating layer and in the opening;
forming the first conductive layer on the first seed layer; and
forming a second insulating layer on the first conductive layer after the conductive bump is formed.

18. The manufacturing method of the electronic device of claim 17, further comprising:
removing the substrate and the seed layer; and
forming a conductive member on a lower surface of the first insulating layer, so that the conductive member is electrically connected to the other conductive bump.

19. The manufacturing method of the electronic device of claim 17, wherein a method of forming the first conductive layer on the first seed layer and forming the conductive bump comprises:
forming a first photoresist on the first seed layer, wherein the first photoresist has a first opening;
forming the first conductive layer in the first opening;
removing the first photoresist;
forming a second photoresist on the first conductive layer, wherein the second photoresist has a second opening;
forming the conductive bump in the second opening; and
removing the second photoresist.

20. The manufacturing method of the electronic device of claim 17, wherein a method of forming the first conductive layer and the conductive bump comprises:
forming a first photoresist on the first seed layer, wherein the first photoresist has a first opening;
forming the first conductive layer in the first opening;
removing the first photoresist;
forming a second insulating layer on the first conductive layer, wherein the second insulating layer has a third opening; and
forming the conductive bump in the third opening.
